(19) United States
(12) Patent Application Publication
(10) Pub. No.: US 2024/0234290 A1
(43) Pub. Date: Jul. 11, 2024

(54) MULTILAYER SUBSTRATE, METHOD FOR MANUFACTURING SAME, AND ELECTRONIC DEVICE INCLUDING MULTILAYER SUBSTRATE

(71) Applicant: STEMCO CO., LTD., Cheongju-si (KR)

(72) Inventors: Young Jun KIM, Cheongju-si (KR); Dong Gon KIM, Cheongju-Si (KR)

(73) Assignee: STEMCO CO., LTD., Cheongju-si (KR)

(21) Appl. No.: 18/612,076

(22) Filed: Mar. 21, 2024

Related U.S. Application Data
(63) Continuation of application No. PCT/KR2022/014014, filed on Sep. 20, 2022.

(30) Foreign Application Priority Data
Sep. 29, 2021 (KR) 10-2021-0128619

(51) Int. Cl. H01L 23/498; H01F 27/28; H01L 21/48

(52) U.S. Cl. CPC H01L 23/49838; H01F 27/2804; H01L 21/4857; H01L 23/49822; H01F 2027/2809

(57) ABSTRACT

Provided are: a multilayer substrate in which a single portion of leading wiring can be used to increase circuit density and enhance electrical characteristics; a method for manufacturing same; and an electronic device including the multilayer substrate. The multilayer substrate comprises: a plurality of insulating layers each having a defined cut line region; circuits which are formed on the respective insulating layers and including wiring and a plating layer or only wiring; a via formed in at least one insulating layer among the plurality of insulating layers; and leading wiring which is formed on one insulating layer among the plurality of insulating layers and connects the cut line region and the wiring, wherein the plating layers are formed on the surface of the wiring by using an electrical signal supplied to the leading wiring.

### CROSS-REFERENCE TO RELATED APPLICATIONS

This application is a Continuation of International Application No. PCT/KR2022/014014 filed Sep. 20, 2022, which claims benefit of priority to Korean Patent Application No. 10-2021-0128619 filed Sep. 29, 2021, the entire contents of which are incorporated herein by reference.

### TECHNICAL FIELD

The present disclosure relates to a multilayer substrate that can increase circuit density and enhance electrical characteristics, a method for manufacturing the multilayer substrate, and an electronic device including the multilayer substrate.

### BACKGROUND ART

Recently, there has been a demand for high circuit density in circuit boards to maximize the performance of electronic devices. For example, a structure has been proposed that reduces the distance between patterns and improves circuit density by overlapping the patterns to increase the thickness of the patterns.

### DISCLOSURE

### Technical Problems

To enhance electrical characteristics while increasing circuit density, each layer can be formed by overlapping patterns. In this case, lead wiring extending from the patterns to outside a cutline area can be formed for each layer.

However, if the lead wiring is formed in the cutline area of each layer, the thickness of target patterns to be cut may increase. Therefore, when cutting along the cutline area, the presence of the lead wiring formed in each layer may increase the likelihood of burrs and metallic foreign matter, potentially degrading the appearance and quality of a product. Furthermore, parts of wirings may be excessively exposed on the sides of the circuit board, potentially causing noise during circuit operation.

While it is possible to remove the lead wiring before forming the circuitry of an upper layer, this may require additional processes such as masking off wiring areas except for the lead wiring to be removed, which may decrease productivity.

The technical challenge to be solved by the present disclosure is to provide a multilayer substrate that can increase circuit density and enhance electrical characteristics using a single lead wiring, a method for manufacturing the multilayer substrate, and an electronic device including the multilayer substrate.

The technical challenges of the present disclosure are not limited to those mentioned above, and other technical challenges not mentioned will become clear to those skilled in the art from the following description.

### Technical Solutions

According to an aspect of the present disclosure, a multilayer substrate includes: a plurality of insulating layers in which a cutline area is defined; circuits formed on the respective insulating layers and including either wiring with a plating layer formed on a surface thereof or wiring with no plating layer formed thereon; vias formed in at least one of the insulating layers; and lead wiring formed on one of the insulating layers where circuits connected to one another via the vias are formed, the lead wiring extending to the cutline area.

If a second insulating layer, where circuits with the plating layer are formed, is not present on a first insulating layer, where circuits with no plating layer are formed, the vias may be formed in each of the insulating layers that range from the insulating layer where the lead wiring is formed to the insulating layer below the first insulating layer.

A thickness of the wiring may be between 40 μm and 200 μm.

A spacing between the circuits may be 2 μm and 8 μm if the circuits include both the wiring and the plating layer formed on the surface of the wiring.

The spacing between the circuits may be 10 μm and 30 μm if the circuits include the wiring with no plating layer formed thereon.

The plating layer may be formed on the surface of the wiring that is electrically connected to the lead wiring via the vias.

The lead wiring may be additionally formed on one of the insulating layers where the vias are not formed.

The circuits formed on the same layer as the lead wiring may include both the wiring and the plating layer.

The lead wiring may be formed with the same level as or a lower level than the wiring.

If the lead wiring is formed at a lower level than the wiring, the lead wiring may be formed with the same level as a seed layer formed between the corresponding insulating layer and the wiring.

The plating layer may not be formed on a surface of the lead wiring.

The multilayer substrate may further include a lead wiring protective layer formed on the lead wiring.

The lead wiring protective layer may be removed after the formation of the plating layer on the wiring or may remain when the insulating layers are stacked on the circuits.

The lead wiring protective layer may be formed with the same level as the wiring or as a combined height of the wiring and the plating layer.

The lead wiring may be formed with the same level as the wiring that is formed at the same layer as the lead wiring, and the lead wiring protective layer may be formed with the same level as the plating layer.

The insulating layer where the lead wiring is formed may protrude outwardly beyond the cutline area, and the lead wiring may be formed on the corresponding insulating layer to extend outwardly beyond the cutline area.

Also, according to an aspect of the present disclosure, an electronic device includes: a multilayer substrate; and a semiconductor device electrically connected to the multilayer substrate, wherein the electronic device operates under the control of the semiconductor device or uses an electromagnetic force provided by circuits formed on the multilayer substrate.

Also, according to an aspect of the present disclosure, a method for manufacturing a multilayer substrate includes: providing a first insulating layer, which has a cutline defined therein and includes a projected area that protrudes outwardly beyond the cutline area; forming first wiring and lead wiring, which is connected to the first wiring to extend to the projected area of the first insulating layer, on the first insulating layer; forming an n-th insulating layer, an (n−1)-th via, and n-th wiring by repeating n times a step of sequentially forming an insulating layer on a first circuit, which includes the first wiring, a via, which penetrates the insulating layer, and wiring on the via and the insulating layer; forming a protective layer on an n-th circuit including the n-th wiring; and removing the projected area that protrudes outwardly beyond the cutline area, by cutting along the cutline area, wherein n is a natural number equal to or greater than 2, the n-th insulating layer has defined therein a cutline area corresponding to a cutline area of the first insulating layer and has the lead wiring formed thereon in the projected area to be exposed, and a plating layer is formed on a surface of the wiring of at least one of the first through n-th circuits.

The method may further include, after the forming the second wiring, forming a second plating layer on a surface of the second wiring by applying an electrical signal to the lead wiring.

If the second circuit is not an uppermost circuit of the multilayer substrate, an N-th circuit (where N is a natural number of 3 or greater) is formed by repeating a step of stacking another insulating layer and circuit on the second circuit, and the protective layer may be formed on the N-th circuit.

A plating layer may be formed on at least one of the third through N-th wirings of the third through N-th circuits.

If the first insulating layer includes a metal layer on its surface and the metal layer is formed as the lead wiring, the method may further include forming a lead wiring protective layer on the metal layer.

The plating layer may be formed using the lead wiring.

The specific details of other embodiments are included in the detailed description and accompanying drawings.

### Advantageous Effects

The present disclosure relates to a multilayer substrate capable of increasing circuit density and enhancing electrical characteristics, a method for manufacturing the multilayer substrate, and an electronic device including the multilayer substrate, and can achieve the following benefits.

First, since lead wiring does not need to be formed in each layer, the thickness of a target pattern to be cut can be reduced, thereby ensuring quality for the appearance of the product, including the cutline area.

Second, it is possible to reduce the amount of metal exposed on the sides of a product and to reduce circuit noise.

Third, efficient lead wiring design facilitates external shaping and enables the implementation of high-density circuits.

The effects of the present disclosure are not limited to those mentioned above, and other effects not mentioned will be clearly understood by those skilled in the art from the description below.

### BRIEF DESCRIPTION OF DRAWINGS

FIG. 1 is a cross-sectional view illustrating the structure of a multilayer substrate according to a first embodiment of the present disclosure;

FIG. 2 is an illustrative diagram for explaining the structure of wiring and a plating layer that form a circuit of a multilayer substrate according to some embodiments of the present disclosure;

FIG. 3 is an illustrative diagram for explaining how to plate the wiring and plating layer of a circuit of a multilayer substrate according to some embodiments of the present disclosure;

FIG. 4 is a cross-sectional view illustrating the structure of a multilayer substrate according to a second embodiment of the present disclosure;

FIG. 5 is an illustrative diagram for explaining the role of lead wiring in configuring the multilayer substrate according to some embodiments of the present disclosure;

FIG. 6 is a first illustrative diagram for explaining the configuration of lead wiring in the multilayer substrate according to some embodiments of the present disclosure;

FIG. 7 is a second illustrative diagram for explaining the configuration of lead wiring in the multilayer substrate according to some embodiments of the present disclosure;

FIG. 8 is a third illustrative diagram for explaining the configuration of lead wiring in the multilayer substrate according to some embodiments of the present disclosure;

FIG. 9 is a first illustrative diagram for explaining the configuration of the lead wiring protective layer in the multilayer substrate according to some embodiments of the present disclosure;

FIG. 10 is a second illustrative diagram for explaining the configuration of the lead wiring protective layer in the multilayer substrate according to some embodiments of the present disclosure;

FIG. 11 is a cross-sectional view illustrating the structure of a multilayer substrate according to a third embodiment of the present disclosure;

FIG. 12 is a cross-sectional view illustrating the structure of a multilayer substrate according to a fourth embodiment of the present disclosure;

FIG. 13 is a cross-sectional view illustrating the structure of a multilayer substrate according to a fifth embodiment of the present disclosure; and

FIG. 14 is a flowchart illustrating a method for manufacturing the multilayer substrate according to the first embodiment of the present disclosure.

### BEST MODES FOR CARRYING OUT THE INVENTION

Embodiments of the present disclosure will hereinafter be described with reference to the accompanying drawings. For the same components in the drawings, the same reference numerals are used, and redundant descriptions thereof will be omitted.

The present disclosure relates to a multilayer substrate that can increase circuit density and enhance electrical characteristics using a single lead wiring, a method for manufacturing the multilayer substrate, and an electronic device including the multilayer substrate. That is, the first objective of the present disclosure is to secure the reliability of multilayer substrate cutting lines by reducing lead wiring. The present disclosure will hereinafter be described in detail with reference to the drawings.

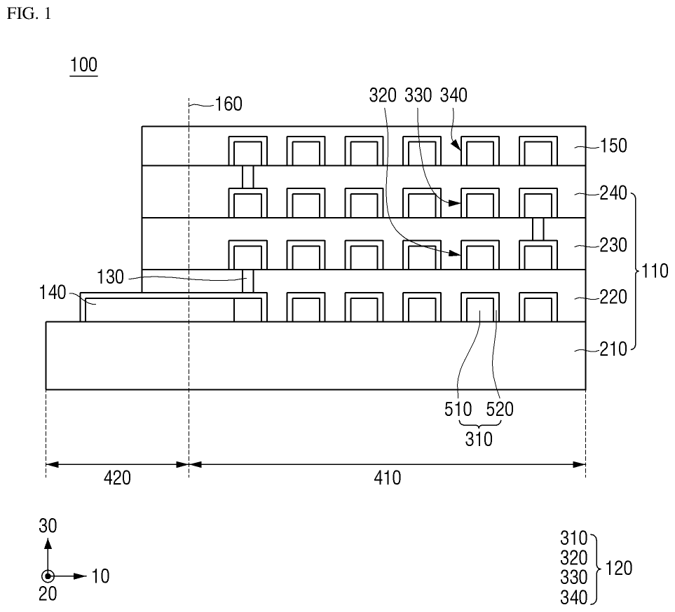

FIG. 1 is a cross-sectional view illustrating the structure of a multilayer substrate according to a first embodiment of the present disclosure.

Referring to FIG. 1, a multilayer substrate 100 may include an insulation layer 110, circuits 120, vias 130, lead wiring 140, and a protective layer 150.

The multilayer substrate 100, which is a multilayer circuit board, may include a plurality of insulating layers 110 and a plurality of circuits 120. In this case, the circuits 120 may be formed on each of the insulating layers 110.

In FIG. 1, the multilayer substrate 100 is illustrated as including four insulation layers 210, 220, 230, and 240 and four circuits 310, 320, 330, and 340, but the present embodiment is not limited thereto. It should be understood that the present disclosure can also be applied to cases where the multilayer substrate 100 includes two insulating layers and two circuits, or more than four insulating layers and more than four circuits.

The insulating layers 110, which are base materials formed on each layer to construct a multilayer circuit board, may be formed with a predetermined thickness (e.g., 5 μm to 100 μm) using an insulating material. The insulating layers 110 may be formed to have one of the following properties: rigidity, flexibility, or rigidity-flexibility.

Each of the insulating layers 110 may include a cutline area 160. Here, the cutline area 160 is a boundary part that divides the circuit board into a product area 410 and a non-product area 420. The non-product area 420 refers to the area protruding outwardly from the cutline area 160. Cutting may be performed along the cutline area 160 during a production process using a technique such as laser or dicing, thereby separating the product area 410 from the non-product area 420. The cutline area 160 may be an edge area of the multilayer substrate 100 that consists only of the product area 410 or may be an area positioned on an inner side of the edge area.

A plurality of insulating layers 110 may be formed within the multilayer substrate 100. For example, four insulating layers may be formed within the multilayer substrate 100, in which case, the multilayer substrate 100 may include first, second, third, and fourth insulating layers 210, 220, 230, and 240.

The first, second, third, and fourth insulating layers 210, 220, 230, and 240 may be formed with the same thickness, but the present embodiment is not limited thereto. Alternatively, some of the first, second, third, and fourth insulating layers 210, 220, 230, and 240 may be formed with the same thickness, while the other insulating layers may be formed with different thicknesses. Yet alternatively, the first, second, third, and fourth insulating layers 210, 220, 230, and 240 may all be formed with different thicknesses.

Although not illustrated in FIG. 1, a seed layer may be formed on each of the first, second, third, and fourth insulating layers 210, 220, 230, and 240. The seed layer may be formed of an electrically conductive material and may be formed on the first, second, third, and fourth insulating layers 210, 220, 230, and 240 using a physical or chemical method such as deposition, adhesion, plating, etc. For example, the seed layer may be formed of one selected metal from among conductive metals such as nickel (Ni), chromium (Cr), copper (Cu), gold (Au), aluminum (Al), and palladium (Pd), or an alloy of two or more of these conductive metals.

Additionally, a backing layer may be further formed on the seed layer. Like the seed layer, the backing layer may be formed of a conductive metal. The backing layer may be formed of the same metal as, or a different metal from, the seed layer. The backing layer may be formed with the same thickness as, or a greater thickness than, the seed layer and may be thinner than the circuits 120.

The circuits 120 may be formed on the insulating layers 110 to electrically connect, and transmit signals between, semiconductor devices mounted on the multilayer substrate 100 and external electronic devices. The circuits 120 may also be formed on the insulating layers 110 to induce electromotive force. In this case, each of the circuits 120 may be wound in a spiral on the insulating layers 110 to form a coil pattern.

The circuits 120 may be formed of an electrically conductive material. For example, the circuits 120 may be formed of a material selected from among conductive metals such as Ni, Cr, Cu, Au, silver (Ag), platinum (Pt), Al, Pd, and titanium (Ti), or an alloy of two or more of these conductive metals.

The circuits 120 may be formed on the insulating layers 110 using a plating process. Specifically, the circuits 120 may be formed on the insulating layers 110 using either electrolytic plating or electroless plating. However, the present embodiment is not limited thereto. The circuits 120 may also be formed on the insulating layers 110 using various other techniques such as etching, printing, and coating.

A plurality of circuits 120 may be formed within the multilayer substrate 100. For example, four circuits may be formed within the multilayer substrate 100, in which case, the multilayer substrate 100 may include first, second, third, and fourth circuits 310, 320, 330, and 340.

The number of circuits 120 formed within the multilayer substrate 100 may be the same as the number of insulating layers 110. That is, a circuit 120 may be formed on each of the insulating layers 110. However, the present embodiment is not limited to this. Alternatively, fewer circuits 120 than there are insulating layers 110 may be formed. In this case, there may be some layers that consist only of the insulating layers 110 because of the circuits 120 not being formed on the insulating layers 110.

The first circuit 310 may be configured to include wiring 510 and a plating layer 520. In this case, the wiring 510 may be formed on the first insulating layer 210, and the plating layer 520 may be formed to surround the wiring 510. In a case where a seed layer or backing layer is formed on the first insulating layers 210, the wiring 510 may be formed on the corresponding seed or backing layer.

The following will describe the wiring 510 and the plating layer 520 that constitute the first circuit 310, but it should be understood that the second circuit 320, the third circuit 330, and the fourth circuit 340 may also be formed with the same structure as the first circuit 310.

The wiring 510, which serves as a conductive pattern, may be formed on a seed layer using electrolytic plating. For example, the wiring 510 may be generated using a semi-additive process (SAP) method by forming a seed layer on the insulating layer 110 and then forming a circuit 120 on the seed layer using electrolytic plating.

The plating layer 520, like the wiring 510, serves as a conductive pattern and may be formed to surround the surface of the wiring 510 using electrolytic plating. The plating layer 520 may be formed to surround the entire exposed surface of the wiring 510, or may be formed to surround only part of the exposed surface of the wiring 510.

First, second, third, and fourth circuits 310, 320, 330, and 340 may each consist only of the wiring 510. For example, in a particular layer with a greater number of windings compared to other layers or for the purpose of increasing the resistance of the particular layer, each of the first, second, third, and fourth circuits 310, 320, 330, and 340 may be configured to include only the wiring 510.

Besides the first objective described earlier, the present disclosure also aims to increase circuit density by narrowing inter-wiring (510) spacing and to enhance electrical characteristics (e.g., electromotive force).

To increase circuit density solely using the wiring 510, the thickness and width of the wiring 510 may be increased. However, in this case, the width of photoresist corresponds to the inter-wiring (510) spacing. That is, the photoresist used to form the wiring 510 become very narrow. Thus, it is challenging to form a photoresist layer into a pattern using a developer or to remove the photoresist pattern formed between the wiring 510 using a stripper. Additionally, narrow spacing requires high-resolution exposure of the photoresist, which may lead to losses in terms of quality and cost.

Consequently, achieving the aforementioned objectives using only the wiring 510 is challenging. Therefore, it is preferable to configure at least one of the first, second, third, and fourth circuits 310, 320, 330, and 340 to include both the wiring 510 and the plating layer 520.

Meanwhile, when all the first, second, third, and fourth circuits 310, 320, 330, and 340 each include both the wiring 510 and the plating layer 520, the inter-wiring (510) spacing can be reduced, and the cross-sectional area of the wiring can also be enhanced. For example, according to the present disclosure, the inter-wiring (510) spacing can be reduced to a range of 5 μm to 10 μm (preferably, 6 μm).

A plating layer 520 may be formed to cover the top and side surfaces of the wiring 510. The plating layer 520 may be formed to cover the top and side surfaces of the wiring 510 using electrolytic plating or isotropic plating. However, the present embodiment is not limited to this. Alternatively, the plating layer 520 may also be formed to cover only the top surface or the side surfaces of the wiring 510. Yet alternatively, the plating layer 520 may cover only one side surface and the top surface of the wiring 510.

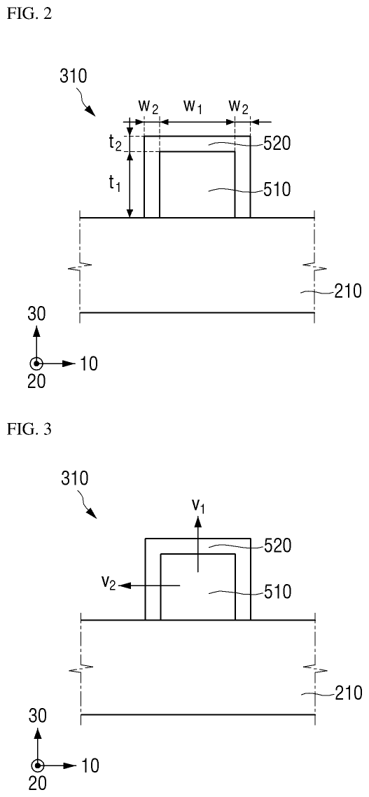

Referring to FIG. 2, the plating layer 520 may be formed with a smaller thickness than the wiring 510 (t₂<t₁), but the present embodiment is not limited thereto. The plating layer 520 may also be formed with the same thickness as the wiring 510 (t₂=t₁) or with a greater thickness than the wiring 510 (t₂>t₁).

Similarly, the plating layer 520 may be formed with a smaller width than the wiring 510 (w₂<w₁), but the present embodiment is not limited thereto. The plating layer 520 may also be formed with the same width as the wiring 510 (w₂=w₁) or with a greater width than the wiring 510 (w₂>w₁).

As previously described, the plating layer 520 may be formed to cover the top and side surfaces of the wiring 510. In this case, the thickness and width of the plating layer 520 may be the same (t₂=w₂), but the present embodiment is not limited thereto. The thickness and width of the plating layer 520 may be different. For example, the thickness of the plating layer 520 may be greater than its width (t₂>w₂), or the width of the plating layer 520 may be greater than its thickness (t₂<w₂). FIG. 2 is an illustrative diagram for explaining the structure of the wiring and plating layer that form a circuit of a multilayer substrate according to some embodiments of the present disclosure.

The description will be continued, referring back to FIG. 1.

The plating layer 520 may be formed of an electrically conductive material of the same composition as the wiring 510, but the present embodiment is not limited thereto. Alternatively, the plating layer 520 may be formed of an electrically conductive material of a different composition than the wiring 510. Yet alternatively, the plating layer 520 may be formed of an electrically conductive material where some components are the same as those of the wiring 510 and others are different.

The plating layer 520 may be formed on the wiring 510 using an isotropic plating method. Here, the isotropic plating method refers to a method where the plating layer 520 grow to a uniform (i.e., identical or similar) thickness. When the plating layer 520 are formed on the wiring 510 using the isotropic plating method, the growth rate (v₁) of the plating layer 520 in the direction of the top surface direction of the wiring 510 may be the same as the growth rate (v₂) of the plating layer 520 in the direction of the side surfaces of the wiring 510 (v₁=v₂).

When the plating layer 520 is formed on the wiring 510 using the isotropic plating method, the variation in thickness across the first circuit 310 can be reduced, and the cross-sectional area of the first circuit 310 can be increased, thereby reducing the inter-wiring (510) spacing. Consequently, the present disclosure can achieve a high aspect ratio (AR) for the inter-wiring spacing.

In the SAP method, plating resist patterns may be formed in the space areas between circuits. The shape of the plating resist patterns is maintained, and the space width between parts of wiring is influenced by the thickness of the wiring when forming the wiring through plating. For example, if the thickness of the wiring is between 40 μm and 200 μm, a plating resist pattern width of about 10 μm to 30 μm is required to form the wiring. If the width of the plating resist patterns narrows, there may be issues with pattern damage during processing, and when the resist patterns are removed with a stripper after the formation of the wiring, there may be a problem with residues from the plating resist patterns because the stripper does not sufficiently penetrate the space between parts of the wiring. Ultimately, forming wiring using the SAP method has limitations in significantly increasing the cross-sectional area of circuits, such as coils, due to the inter-wiring spacing.

To solve this, in the present embodiment, the wiring 510 may be formed first using the SAP method, and then the plating layer 520 may be formed on the surface of the wiring 510 to increase the cross-sectional area of the circuit 120. In this case, the circuit 120 with the plating layer 520 formed on the surface of the wiring 510 may be formed through electrolytic isotropic plating, thereby increasing the cross-sectional area of the circuit 120 and reducing the inter-circuit spacing to a level of 2 μm to 8 μm.

Specifically, if the wiring is formed with a thickness and width of 46 μm, the inter-wiring spacing becomes approximately 13 μm. Then, if the plating layer is formed to a level of 3 μm on the surface of the wiring through isotropic plating, the width of the circuit including the wiring and the plating layer becomes approximately 52 μm, increasing the cross-sectional area, and reducing the inter-circuit spacing to approximately 7 μm.

Here, when the thickness of the wiring is less than 40 μm, it is possible to narrow the inter-wiring spacing. Thus, forming the plating layer may be unnecessary. However, in some cases, the formation of the plating layer may be required depending on the working environment, design, or material characteristics.

Additionally, when isotropic plating is performed, plating both sides of the wiring 510 increases the circuit width more than the thickness. This results in a lower AR, which represents the horizontal-to-vertical ratio of the circuit 120 when the plating layer 520 is further formed on the surface of the wiring 510 compared to when the wiring is formed by the SAP method.

Conversely, the plating layer 520 may be formed on the wiring 510 using an anisotropic plating method. The anisotropic plating method, unlike the isotropic plating method, grows the plating layer 520 unevenly in thickness. With anisotropic plating, the growth rate (v₁) of the plating layer 520 on the top surface of the wiring 510 may differ from the growth rate (v₂) of the plating layer 520 on the side surfaces of the wiring 510 (v≠v₂).

Meanwhile, in the present embodiment, it is possible to form the wiring 510 using the anisotropic plating method and form the plating layer 520 using the isotropic plating method. If the circuit 120 is formed in this manner when the multilayer substrate 100 is a coil substrate, it can lead to an increase in the cross-sectional area of the coil and a reduction in the resistance of the coil, thereby enhancing the coil's characteristics. FIG. 3 is an illustrative diagram for explaining how to plate the wiring and plating layer of a circuit of the multilayer substrate according to some embodiments of the present disclosure.

The description will be continued, referring back to FIG. 1.

As previously explained, to meet both the first and second objectives of the present disclosure, a plurality of circuits 120 may each include both the wiring 510 and the plating layer 520, but the present embodiment is not limited thereto. Alternatively, it is also possible that while some of the circuits 120 may include both the wiring 510 and the plating layer 520, others may include only the wiring 510.

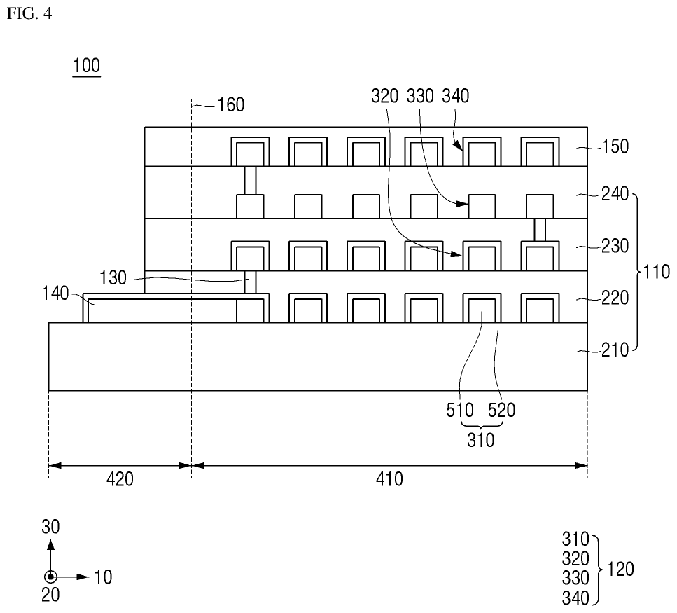

For example, if the circuits 120 include the first, second, third, and fourth circuits 310, 320, 330, and 340, as illustrated in FIG. 4, each of the first, second, and fourth circuits 310, 320, and 340 may be configured to include both the wiring 510 and the plating layer 520, while the third circuit 330 may be configured to include only the wiring 510.

If the circuits 120 are formed in this manner, it is possible to reduce the size of the circuit board 100 while maintaining the electrical characteristics (i.e., electromotive force) required for driving an external electronic device (e.g., a camera actuator) with the same level as or a similar level to that in a case where all the first, second, third, and fourth circuits 310, 320, 330, and 340 are each configured to include both the wiring 510 and the plating layer 520. FIG. 4 is a cross-sectional view illustrating the structure of a multilayer substrate according to a second embodiment of the present disclosure.

The description will be continued, referring back to FIG. 1.

The vias 130 are for electrically connecting the circuits 120, which are formed in different layers, in a vertical direction (or a third direction 30). Each of the vias 130 may be formed in a hole shape, penetrating the lower of two vertically aligned insulating layers 110, and may be filled with an electrically conductive material. A single via 130 or multiple vias 130 may be formed at each level.

The vias 130 may be formed to have the same width in the third direction 30, but the present embodiment is not limited thereto. Alternatively, the vias 130 may be formed to widen or narrow in width in the third direction 30.

The lead wiring 140 is for plating (e.g., electroplating) the layers of the wiring 510 in the multilayer substrate 100. The lead wiring 140 may be formed on any one of the insulating layers 110. For example, the lead wiring 140 may be formed on the first insulating layer 210, which forms the lowermost layer among the first, second, third, and fourth insulating layers 210, 220, 230, and 240.

The lead wiring 140 allows current from an external source to be applied to the wiring 510, enabling the formation of plating layer 520 on the wiring 510. To achieve this, the lead wiring 140 may be formed to extend from the ends of the insulating layers 110 to an outermost part of the wiring 510 and thus to be connected to wiring 510. Moreover, to enable the formation of the plating layer 520 on the layers of the wiring 510, the layers of the wiring 510 may be electrically connected via the vias 130.

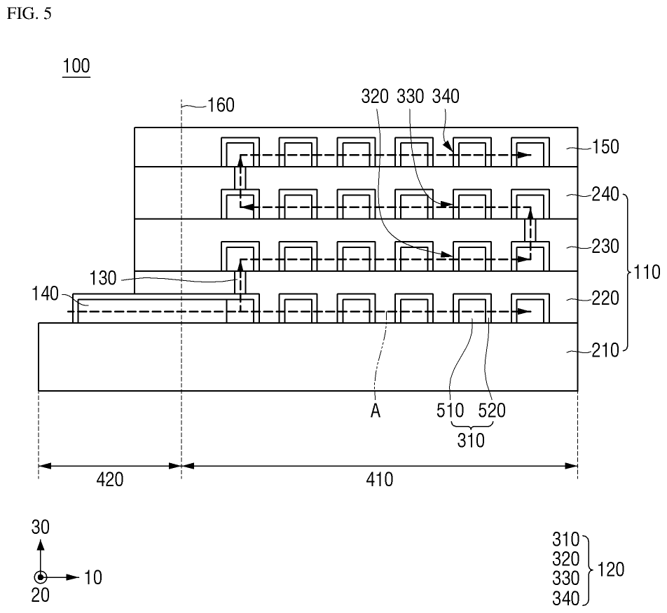

In the present embodiment, referring to FIG. 5, the multilayer substrate 100 can apply current A to the wiring 510 formed on each of the insulating layers 210, 220, 230, and 240 through the vias 130 and the lead wiring 140. Thus, in the present disclosure, the lead wiring 140 does not need to be formed on each of the insulating layer 210, 220, 230, and 240, and the plating layer 520 can be effectively formed on any desired layer of the wiring 510. Additionally, by reducing the number of lead wirings 140, the amount of metal exposed in the cutline area 160 can be significantly reduced, and noise generated in the circuits 120 of the multilayer substrate 100 can be lowered accordingly.

Consequently, in the present embodiment, the multilayer substrate 100 can facilitate easy external shaping and high-density circuit implementation through efficient lead wiring design. FIG. 5 is an illustrative diagram for explaining the role of lead wiring in configuring the multilayer substrate according to some embodiments of the present disclosure.

The lead wiring 140 may be formed on an insulating layer 110 where a circuit 120 including both the wiring 510 and the plating layer 520 is formed. In other words, the lead wiring 140 may not be formed on an insulating layer 110 where a circuit 120 only including the wiring 510 is formed.

The lead wiring 140 may be formed with the same level as the wiring 510. Here, the expression “the same level” means that both wirings have substantially the same height or similar heights from the surface of the insulating layer 110. That is, referring to FIG. 6, when the lead wiring 140 is formed with the same level as the wiring 510, it means that the height (h) of the lead wiring 140 is substantially the same as the height (h) of wiring 510 (h₁=h₂). FIG. 6 is a first illustrative diagram for explaining the configuration of lead wiring in the multilayer substrate according to some embodiments of the present disclosure.

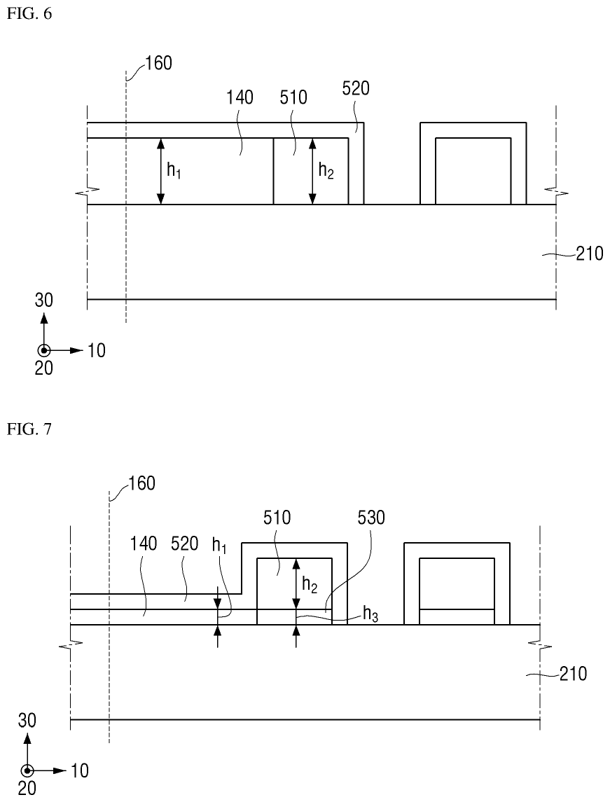

Alternatively, the lead wiring 140 may be formed at a different level from the wiring 510. In this case, the lead wiring 140 may be formed at a lower level than the wiring 510 (h₁<h₂). For example, referring to FIG. 7, if a seed layer 530 is formed on the first insulating layer 210 and the wiring 510 is formed on the seed layer 530, the lead wiring 140 may be formed to have the same level as the seed layer 530 (h₁=h₁<h₂). FIG. 7 is a second illustrative diagram for explaining the configuration of lead wiring in the multilayer substrate according to some embodiments of the present disclosure.

When current is applied to the wiring 510 through the lead wiring 140, the plating layer 520 may be formed on both the lead wiring 140 and the wiring 510, as illustrated in FIGS. 6 and 7. After removing the seed layer 530, where no wiring 510 is formed, the plating layer 520 may be formed by applying current, but the present embodiment is not limited thereto.

Alternatively, referring to FIG. 8, the plating layer 520 may be formed only on the wiring 510, and not on the lead wiring 140. FIG. 8 is a third illustrative diagram for explaining the configuration of lead wiring in the multilayer substrate according to some embodiments of the present disclosure.

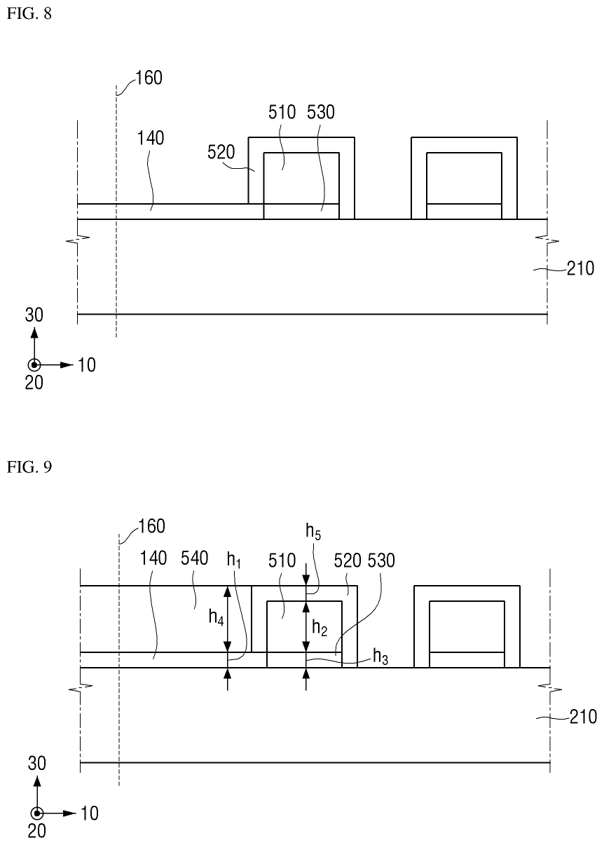

A lead wiring protective layer 540 may be formed on the lead wiring 140. For example, if the lead wiring 140 is formed at a lower level than the wiring 510, the lead wiring protective layer 540 may be formed on the lead wiring 140. The presence of the lead wiring protective layer 540 on the lead wiring 140 may prevent the formation of the plating layer 520 on the lead wiring 140. The lead wiring protective layer 540 may be removed after the formation of the plating layer 520 on the wiring 510, and may also remain after another insulating layer 110 is stacked on the plating layer 520, as illustrated in FIG. 9. FIG. 9 is a first illustrative diagram for explaining the configuration of the lead wiring protective layer in the multilayer substrate according to some embodiments of the present disclosure.

The lead wiring protective layer 540 may be formed with the same level as the height (h) of the wiring 510 (h₄=h₂). Alternatively, the lead wiring protective layer 540 may be ₂₄₂ formed at a level equal to the combined height (h₂+h₃) of the wiring 510 and the plating layer ₂₃ 520 (h₄=h₂+h₃). If the lead wiring protective layer 540 is formed in this manner, issues with ₄₂₃ unevenness can be prevented when stacking another insulating layer 110 on the lead wiring protective layer 540.

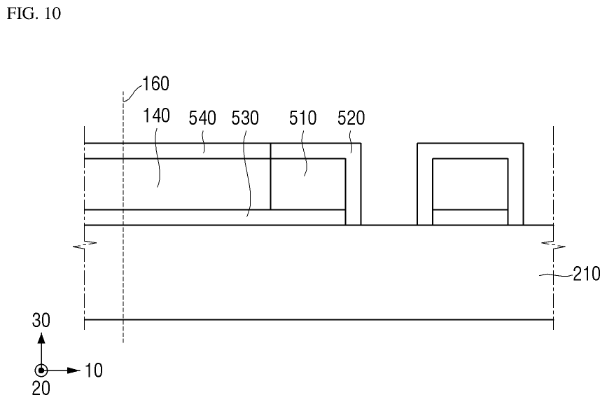

Meanwhile, if the lead wiring 140 is formed with the same level as the wiring 510, the lead wiring protective layer 540, which is formed on the lead wiring 140, may be with the same level as the plating layer 520, as depicted in FIG. 10. FIG. 10 is a second illustrative diagram for explaining the configuration of the lead wiring protective layer in the multilayer substrate according to some embodiments of the present disclosure.

Additionally, the lead wiring protective layer 540 may be formed to contact the wiring 510, but alternatively, the lead wiring protective layer 540 may be formed at a predetermined distance from the wiring 510. In the former case (where the lead wiring protective layer 540 contacts the wiring 510), the plating layer 520 may be formed to cover the top surface and one side surface of the wiring 510. In the latter case (where the lead wiring protective layer 540 is formed at a predetermined distance from the wiring 510), the plating layer 520 may be formed to cover the top surface and both side surfaces of the wiring 510. The plating layer 520 may be formed in various shapes depending on the configuration of the lead wiring protective layer 540.

The description will be continued, referring back to FIG. 1.

As mentioned earlier, the lead wiring 140 may enable the plating layer 520 to be formed on all the layers of the wiring 510 that are electrically connected through the vias 130. Alternatively, the lead wiring 140 may enable the plating layer 520 to be formed only on some of the layers of the wiring 510 that can be connected through the vias 130. An example of the former case is as illustrated in FIG. 1, and an example of the latter case is as illustrated in FIG. 4.

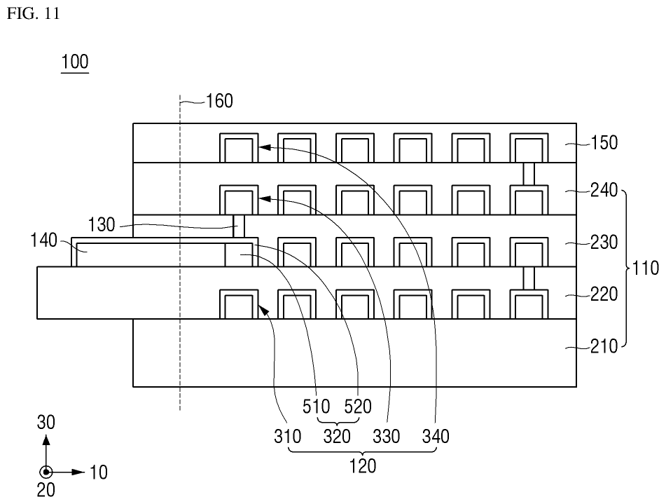

Meanwhile, the lead wiring 140 may not be formed on the lowermost insulating layer 110, but may be on an intermediate insulating layer 110. For example, referring to FIG. 11, the lead wiring 140 may be formed on the second insulating layer 220. In this example, the second circuit 320 may be formed to include both the wiring 510 and the plating layer 520. If the second circuit 320 is electrically connected not only to the third and fourth circuits 330 and 340 thereabove, but also to the first circuit 310 therebelow, through the vias 130, then each of the first, third, and fourth circuits 310, 330, and 340 may also be formed to include both the wiring 510 and the plating layer 520. FIG. 11 is a cross-sectional view illustrating the structure of a multilayer substrate according to a third embodiment of the present disclosure.

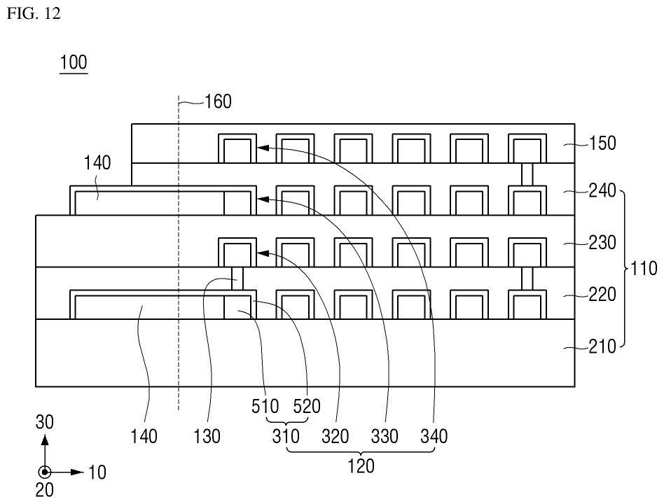

Meanwhile, not all the circuits 120 in the multilayer substrate 100 may be electrically connected through the vias 130. For example, referring to FIG. 12, the first and second circuits 310 and 320 may be electrically connected through the vias 130, and similarly, the third and fourth circuits 330 and 340 may be electrically connected through the vias 130. However, the second and third circuits 320 and 330 may not be electrically connected.

In this case, if the lead wiring 140 is connected to the first circuit 310, each of the first and second circuits 310 and 320 may be formed to include the wiring 510 and the plating layer 520 using the current supplied by the lead wiring 140. However, since the second and third circuits 320 and 330 are not electrically connected, the third and fourth circuits 330 and 340 cannot receive the current through the lead wiring 140 and thus cannot be formed to include the plating layer 520 on the wiring 510. Therefore, in this case, another lead wiring 140 may be additionally installed to be connected to one of the third and fourth circuits 330 and 340. FIG. 12 is a cross-sectional view illustrating the structure of a multilayer substrate according to a fourth embodiment of the present disclosure.

The description will be continued, referring back to FIG. 1.

The protective layer 150 may be formed to cover and protect the uppermost circuit 120. The protective layer 150 may be formed of an insulating material, such as solder resist, and may be formed to cover the uppermost circuit 120 using various methods, such as printing, adhesion, coating, or photolithography.

In the present embodiment, the first insulating layer 210, which is the lowermost insulating layer, may be defined as a base film, and the second, third, and fourth insulating layers 220, 230, and 240, disposed on the first insulating layer 210, may be defined as interlayer insulating layers. In this case, the circuits 120, the vias 130, the lead wiring 140, and the protective layer 150 may be formed on one surface of the base film, i.e., the first insulating layer 210, as illustrated in FIG. 1.

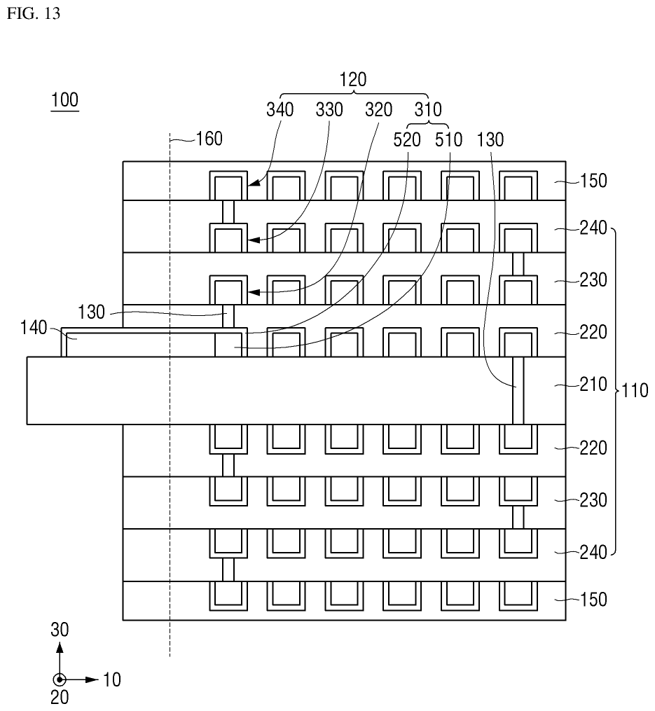

However, the present embodiment is not limited to this. Alternatively, referring to FIG. 13, the circuit 120, the vias 130, the lead wiring 140, and the protective layer 150 may be formed on both surfaces of the base film, i.e., the first insulating layer 210. In this case, the numbers of circuits 120 formed on either surface of the base film may be the same or different. FIG. 13 is a cross-sectional view illustrating the structure of a multilayer substrate according to a fifth embodiment of the present disclosure.

As described with reference to FIGS. 1 through 13, various embodiments of the multilayer substrate 100 have been explained. The present disclosure relates to a multilayer substrate 100 where wiring 510 with a plating layer 520 formed thereon constitutes each circuit 120 using lead wiring 140, and particularly, to a multilayer substrate 100 for an efficient arrangement of the lead wiring 140 on a circuit board.

The multilayer substrate 100 of the present disclosure may form the plating layer 520 on N layers of the wiring 510 by applying current through the vias 130 from the lead wiring 140, formed on one of the layers. Here, N is a natural number greater than or equal to 1.

The multilayer substrate 100 is applicable to an electronic device. The electronic device may be an electric motor, an antenna, a generator, a filter, an inductor, a magnetic disc, a camera module, etc., but the present disclosure is not limited thereto. For example, if the multilayer substrate 100 is a coil substrate, the multilayer substrate 100 may be included in a camera actuator to function as a drive coil within a camera module. The camera actuator may include the multilayer substrate 100 within a housing and may also include a magnetic body installed at a distance from the multilayer substrate 100 within the housing.

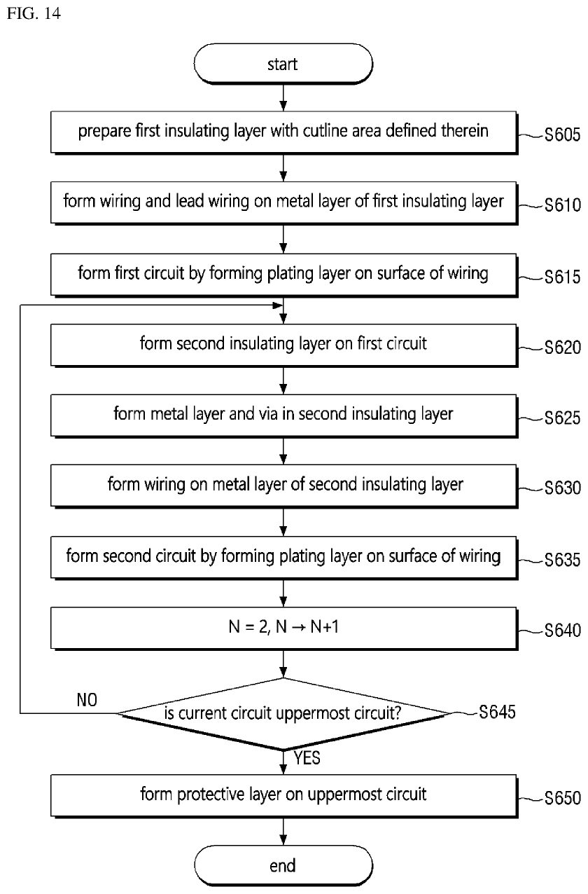

A method for manufacturing the multilayer substrate 100 will hereinafter be described. FIG. 14 is a flowchart illustrating a method for manufacturing the multilayer substrate according to the first embodiment of the present disclosure.

The manufacturing method for the multilayer substrate 100 of FIG. 1 will hereinafter be described with reference to FIG. 14, but it should be understood that the multilayer substrates 100 of FIGS. 4, 11, 12, and 13 can also be manufactured in the same manner as or a similar manner to that of FIG. 1. The description that follows refers to FIGS. 1 and 14.

First, the first insulating layer 210, where the cutline area 160 is defined, is prepared (S605). Here, the first insulating layer 210 may have a metal layer formed on one of its surfaces. The metal layer may be a seed layer 530 or may include the seed layer 530 and a backing layer. The seed layer 530 and the backing layer are conductive metal layers. For example, the seed layer 530 may be provided as a Ni/Cr layer, and the backing layer may be provided as a Cu layer.

Meanwhile, in a case where the multilayer substrate 100 is formed as illustrated in FIG. 13, the metal layer may be formed on both surfaces of the first insulating layer 210.

Once the first insulating layer 210 with the metal layer on top is prepared (S610), a photosensitive resin layer (e.g., a dry film resist (DFR) film) is formed on the metal layer, and a plating resist pattern is formed through exposure and development processes.

On the other hand, in the present embodiment, before the formation of the plating resist pattern, a protective layer (or insulating layer) may be formed on the metal layer that will become the lead wiring 140. Then, the surface of the lead wiring 140 can be prevented from being plated during the formation of the wiring 510 and the plating layer 520. Consequently, the lead wiring 140 can be formed with a smaller thickness than the first circuit 310, minimizing the amount of metal remaining in the cutline area 160.

Alternatively, the plating resist pattern may be formed on the metal layer that will become the lead wiring 140. In this case, the surface of the lead wiring 140 can be prevented from being plated during the formation of the wiring 510, and after the removal of the plating resist, a protective layer may be formed on the lead wiring 140 to remain after the removal of the metal layer. Then, the lead wiring 140 can also be prevented from being plated during the formation of the plating layer 520. Consequently, the lead wiring 140 can be formed with a smaller thickness than the first circuit 310, thereby minimizing the amount of metal remaining in the cutline area 160.

Thereafter, a pattern layer is formed on the metal layer of the first insulating layer 210 using a plating method (S610). The pattern layer may be provided as a Cu metal layer, but the present embodiment is not limited thereto.

The pattern layer may include the wiring 510, which is formed in the product area 410 on the inside of the cutline area 160, and the lead wiring 140, which is formed in the non-product area 420 on the outside of the cutline area 160. That is, the wiring 510 and the lead wiring 140 may be formed with the same level.

Thereafter, the plating resist pattern is removed, and the metal layer is removed from inter-wiring space where the wiring 510 and the lead wiring 140 are not formed.

Thereafter, the first circuit 310, which consists of the wiring 510 and the plating layer 520, is formed by applying current to the lead wiring 140 (S615). The plating layer 520 may be formed using an isotropic plating method, as described earlier, and may be provided as a Cu metal layer, but the present embodiment is not limited thereto.

Meanwhile, the plating layer 520 may also be formed on the lead wiring 140. The plating layer 520 may be formed with an equal thickness on the surface of the wiring 510, that is, on the top and side surfaces.

Furthermore, before the formation of the plating layer 520 on the surface of the wiring 510, the protective layer formed on the lead wiring 140 may be removed, enabling the formation of the plating layer 520 even on the lead wiring 140. In this case, the smooth supply of plating current can be facilitated, and the amount of residual metal can be reduced.

Additionally, after the formation of the plating resist pattern, the wiring 510 and the lead wiring 140 may be simultaneously formed through plating, the metal layer may be removed after the formation of the resist pattern, and the protective layer may be formed on the lead wiring 140. In this case, the smooth supply of plating current can be facilitated while ensuring that the plating layer 520 is not formed on the lead wiring 140, and the amount of residual metal can be reduced.

Thereafter, the second insulating layer 220, which is stacked on the first circuit 310 with the plating layer 520 thereon, including the cutline area 160, is formed (S620).

Thereafter, a via 130 is formed in the second insulating layer 220 to expose part of the first circuit 310. Thereafter, a metal layer is then formed on the second insulating layer 220 (S625). The metal layer may be formed not only on the second insulating layer 220 but also within the via 130.

On the other hand, in the present embodiment, it is also feasible to form a metal layer on the second insulating layer 220 first and then form the vias 130.

Moreover, when there is no need for electrical connection between the circuits of lower and upper insulating layers, the vias 130 may not be formed in the upper insulating layer. In this case, if the plating layer 520 needs to be formed on an upper layer of the wiring 510, additional lead wiring 140 may be additionally formed on the corresponding layer.

Thereafter, a photosensitive resin layer is formed on the metal layer of the second insulating layer 220, and a plating resist pattern is formed through exposure and development processes. Thereafter, the wiring 510 is formed on the metal layer of the second insulating layer 220 using a plating process (S630). The wiring 510 on the second insulating layer 220 is formed on the inside of the cutline area 160 not to overlap with the cutline area 160.

Thereafter, the plating resist pattern is removed, and the metal layer in the inter-wiring space where the wiring 510 is not formed is eliminated. Thereafter, the plating layer 520 is formed on the surface of the wiring 510 using the lead wiring 140, thereby forming the second circuit 320, which consists of the wiring 510 and the plating layer 520 (S635). The plating layer 520 may be formed through isotropic plating to achieve an equal thickness on the top and side surfaces of the wiring 510.

However, if the plating layer 520 is not needed in the corresponding circuit, the step of forming the plating layer may be omitted. That is, the multilayer substrate 100 may include circuits where the plating layer 520 is not formed on the wiring 510.

The third insulating layer 230 and the third circuit 330 on the third insulating layer 230, the fourth insulating layer 240 and the fourth circuit 340 on the fourth insulating layer 240, and an M-th insulating layer and an M-th circuit on the M-th insulating layer may be formed in the same manner as the second insulating layer 220 and the second circuit 320 on the second insulating layer 220. In other words, in the present embodiment, steps S620 through S635 may be repetitively performed to form the M-th insulating layer and the M-th circuit on the M-th insulating layer (S640 and S645). Here, M represents a natural number greater than or equal to 3.

Thereafter, the protective layer 150 is formed on the uppermost circuit (i.e., the fourth circuit 340 in the example of FIG. 1) (S650). Once the protective layer 150 is formed, a multilayer circuit board may be completed by cutting along the cutline area 160 (e.g., laser cutting) to eliminate the non-product area 420.

The embodiments of the present disclosure have been described with reference to the attached drawings. However, the present disclosure is not limited to these embodiments and can be manufactured in various different forms. One of ordinary skill in the field of this invention can understand that the invention can be implemented in other specific forms without changing the technical ideas or features of the invention. Therefore, the embodiments described above should be considered in all respects as illustrative and not restrictive.

### INDUSTRIAL APPLICABILITY

The present disclosure can be applied to a circuit board and an electronic device including the circuit board.

What is claimed is:

1. A multilayer substrate comprising:
a plurality of insulating layers in which a cutline area is defined;
circuits formed on the respective insulating layers and including either wiring with a plating layer formed on a surface thereof or wiring with no plating layer formed thereon;
vias formed in at least one of the insulating layers; and
lead wiring formed on one of the insulating layers where circuits connected to one another via the vias are formed, the lead wiring extending to the cutline area.

2. The multilayer substrate of claim 1, wherein
a thickness of the wiring is between 40 μm and 200 μm, or
a spacing between the circuits is 2 μm and 8 μm if the circuits include both the wiring and the plating layer formed on the surface of the wiring, or is 10 μm and 30 μm if the circuits include the wiring with no plating layer formed thereon.

3. The multilayer substrate of claim 1, wherein the plating layer is formed on the surface of the wiring that is electrically connected to the lead wiring via the vias.

4. The multilayer substrate of claim 1, wherein the lead wiring is additionally formed on one of the insulating layers where the vias are not formed.

5. The multilayer substrate of claim 1, wherein the circuits formed on the same layer as the lead wiring includes both the wiring and the plating layer.

6. The multilayer substrate of claim 1, wherein the lead wiring is formed with the same level as or a lower level than the wiring.

7. The multilayer substrate of claim 6, wherein if the lead wiring is formed at a lower level than the wiring, the lead wiring is formed with the same level as a seed layer formed between the corresponding insulating layer and the wiring.

8. The multilayer substrate of claim 1, wherein the plating layer is not formed on a surface of the lead wiring.

9. The multilayer substrate of claim 1, further comprising:
a lead wiring protective layer formed on the lead wiring.

10. The multilayer substrate of claim 9, wherein the lead wiring protective layer is removed after the formation of the plating layer on the wiring or remains when the insulating layers are stacked on the circuits.

11. The multilayer substrate of claim 9, wherein the lead wiring protective layer is formed with the same level as the wiring or as a combined height of the wiring and the plating layer.

12. The multilayer substrate of claim 9, wherein
the lead wiring is formed with the same level as the wiring that is formed at the same layer as the lead wiring, and
the lead wiring protective layer is formed with the same level as the plating layer.

13. The multilayer substrate of claim 1, wherein
the insulating layer where the lead wiring is formed protrudes outwardly beyond the cutline area, and
the lead wiring is formed on the corresponding insulating layer to extend outwardly beyond the cutline area.

14. An electronic device comprising:
the multilayer substrate of any one of claim 1; and
a semiconductor device electrically connected to the multilayer substrate,
wherein the electronic device operates under the control of the semiconductor device or uses an electromagnetic force provided by the circuits formed on the multilayer substrate.

15. A method for manufacturing a multilayer substrate, comprising:
providing a first insulating layer, which has a cutline defined therein and includes a projected area that protrudes outwardly beyond the cutline area;
forming first wiring and lead wiring, which is connected to the first wiring to extend to the projected area of the first insulating layer, on the first insulating layer;
forming an n-th insulating layer, an (n−1)-th via, and n-th wiring by repeating n times a step of sequentially forming an insulating layer on a first circuit, which includes the first wiring, a via, which penetrates the insulating layer, and wiring on the via and the insulating layer;
forming a protective layer on an n-th circuit including the n-th wiring; and
removing the projected area that protrudes outwardly beyond the cutline area, by cutting along the cutline area,
wherein
n is a natural number equal to or greater than 2,
the n-th insulating layer has defined therein a cutline area corresponding to a cutline area of the first insulating layer and has the lead wiring formed thereon in the projected area to be exposed, and
a plating layer is formed on a surface of the wiring of at least one of the first through n-th circuits.

16. The method of claim 15, further comprising:
forming a second plating layer on a surface of the second wiring by applying an electrical signal to the lead wiring.

17. The method of claim 15, wherein
if the second circuit is not an uppermost circuit of the multilayer substrate, an N-th circuit (where N is a natural number of 3 or greater) is formed by repeating a step of stacking another insulating layer and circuit on the second circuit, and
the protective layer is formed on the N-th circuit.

18. The method of claim 17, wherein a plating layer is formed on at least one of the third through N-th wirings of the third through N-th circuits.

19. The method of claim 15, further comprising:
if the first insulating layer includes a metal layer on its surface and the metal layer is formed as the lead wiring, forming a lead wiring protective layer on the metal layer.

20. The method of claim 15, wherein the plating layer is formed using the lead wiring.
